(19) United States
(12) Patent Application Publication
(10) Pub. No.: US 2013/0335663 A1
(43) Pub. Date: Dec. 19, 2013

(54) Array Substrate, LCD Device, and Method for manufacturing Array Substrate

(71) Applicant: Hao Kou, Shenzhen (CN)

(72) Inventor: Hao Kou, Shenzhen (CN)

(21) Appl. No.: 13/575,351

(22) PCT Filed: Jun. 21, 2012
(86) PCT No.: PCT/CN2012/077302

§ 371 Date: Jul. 26, 2012

(30) Foreign Application Priority Data
Jun. 18, 2012 (CN) 201210201027.8

(51) Int. Cl. G02F 1/136; H01L 33/08

(52) U.S. Cl. 349/43; 438/34; 257/E33.055

(57) ABSTRACT

The present disclosure discloses an array substrate, an LCD device and a manufacturing method of the array substrate. The TFT-LCD array substrate includes a metal electrode; the metal electrode includes a conducting layer; one side of the conducting layer is provided with an adhesive layer made of VOₓSi_{y} material, and the other side is provided with a barrier layer. On one side of the metal electrode of the present disclosure, the vanadium metal and the siliceous material in the array substrate (such as glass, n+a-Si layer) generate a chemical reaction, and the vanadium and the siliceous material generate a chemical reaction to generate the adhesive layer made of VOₓSi_{y} material; thus, the metal electrode can be firmly fixed to the glass base material; meanwhile, VOₓSi_{y} has low contact resistance so that the metal layer has better conducting property. The present disclosure also discloses a manufacturing method; the target material of copper-vanadium alloy is only required to be splashed onto the siliceous material of the array substrate to form the metal electrode with the adhesive layer made of VOₓSi_{y} material under certain vacuum and temperature conditions; the manufacturing method is simple and efficient.

### TECHNICAL FIELD

The present disclosure relates to the field of liquid crystal displays (LCDs), and more particularly to an array substrate, an LCD device, and a method for manufacturing an array substrate.

### BACKGROUND

A metal conductor in an array substrate, which is routinely applied to an LCD panel, is an aluminum conductor. The performance characteristics and the operating characteristics of the array substrate depend on the material of each element of the array substrate to a great extent. With the trend and requirement of large size, high definition, and high-speed driving frequency of display terminals, such as LCD televisions, and the like, panel developers have to face the problem of a resistor in an array system and the time delay of the resistor/capacitor generated. The aluminum conductor has high resistivity (˜4 uΩ·cm) so that thin film transistor (TFT) pixels cannot be sufficiently charged. With the wide application of the Hi-Fas (≧120 Hz), this phenomenon will be more obvious.

Compared with the aluminum conductor, the copper conductor has lower resistivity (˜2 uΩ·cm) and higher electromigration resistance, which attracts many engineers of material and process, and has achieved the application of batch production. In the etching process, the copper will create CuFₓ and CuClₓ during the RIE (reactive ion etch). CuFₓ and CuClₓ are in solid state below 200° C. and will not be gasified. Thus, unlike aluminum, copper cannot be used to be made into conductor patterns by the dry etching. To this end, it becomes important to develop an etching liquid used for the wet etching of copper. In addition, copper and glass have poor adhesiveness; a metal layer is required for transition. Copper is easy to react with silicon through the mutual diffusion to generate a chemical compound containing CuSi₃ below 200° C.; very high contact resistance is generated; thus, other metal layers are required for transition.

### SUMMARY

In view of the above-described problems, the aim of the present disclosure is to provide an array substrate, an LCD device, and a method for manufacturing an array substrate, which have a metal electrode with low contact resistance and firm sticking.

The purpose of the present disclosure is achieved by the following technical schemes:

A TFT-LCD array substrate comprises a metal electrode; the metal electrode comprises a conducting layer. One side of the conducting layer is provided with an adhesive layer made of VOₓSi_{y} material, and the other side is provided with a barrier layer.

Preferably, the conducting layer is made of copper-vanadium alloy, wherein the vanadium content is 0.7-2 at %. This is a metal electrode made of target material of the copper-vanadium alloy. The target material of the copper-vanadium alloy is splashed onto a glass substrate; at high temperature and vacuum environment, vanadium accumulates on a surface and reacts with glass to create the adhesive layer made of VOₓSi_{y} material; the conducting layer mainly made of copper material is naturally formed on the adhesive layer. The conducting layer made by the method of the present disclosure has some vanadium residues. Considering the conducting property and the manufacturing cost of the conducting layer, it is a preferable technical scheme to control the vanadium residues at 0.7-2 at %.

Preferably, the conducting layer comprises a first conducting layer integrally formed with the adhesive layer, a second conducting layer integrally formed with the barrier layer, and a third conducting layer independently arranged between the first conducting layer and the second conducting layer. This is another structure of the conducting layer. Because the conducting layer made of target material of the copper-vanadium alloy inevitably has some vanadium residues, the conducting property is reduced. The independent third conducting layer can be arranged to be made of high-purity metal, such as copper, silver, gold and the like, which improves the conducting property of the conducting layer.

Preferably, the first conducting layer and the second conducting layer are made of copper-vanadium alloy, the vanadium content is 0.7-2 at %, and the third conducting layer is made of pure copper material. This is a structure of the first conducting layer and second conducting layer formed by the target material of the copper-vanadium alloy. At certain temperature and vacuum condition, vanadium in the copper-vanadium alloy accumulates onto the surface; the target material of the copper-vanadium alloy on the bottom layer comes into contact with glass to form the adhesive layer and the first conducting layer. The target material of the copper-vanadium alloy on the surface layer comes into contact with oxygen to form the barrier layer and the second conducting layer. In the structure of the metal electrode formed by the method of the present disclosure, the first conducting layer and the second conducting layer have some vanadium residues. Considering the conducting property and the manufacturing cost of the conducting layer, it is a preferable technical scheme to control the vanadium residues at 0.7-2 at %.

Preferably, the barrier layer is made of VOₓ material. Vanadium oxide (VOₓ) is dissolved easily in an etching acid for copper, which ensures the smooth manufacturing of the metal electrode; thus, VOₓ is suitable to be used as the barrier layer of the metal electrode.

An LCD device comprises the TFT-LCD array substrate mentioned above.

A method for manufacturing a TFT-LCD array substrate comprises the following steps:

A. Preparing a target material of a copper-vanadium alloy and a base material of an array substrate; keeping the target material of the copper-vanadium alloy in a solid solution state, and heating the base material; and

B. Paving the target material of the copper-vanadium alloy onto a surface of the base material of the array substrate to form a metal layer with an adhesive layer of VOₓSi_{y} material.

Preferably, in the step A, the target material of the copper-vanadium alloy is kept at 100-150° C.; and the array substrate is heated to 100-150° C. This is a specific temperature range.

Preferably, the method also comprises a step C after the step B: incinerating the array substrate; a vanadium atom in the target material of the copper-vanadium alloy reacts with oxygen; and a barrier layer made of VOₓ material is formed on the other opposite side of the adhesive layer. This is a specific material of the barrier layer. Optionally, the barrier layer made of VOₓSi_{y} can be formed by paving a silicon material to react with vanadium.

Preferably, the step B comprises:

B1. Splashing the target material of the copper-vanadium alloy onto the surface of the base material of the array substrate; and

B2. Annealing in vacuum environment; the vanadium atom in the target material of the copper-vanadium alloy gathers on the surface, and reacts with silicon in the array substrate to form the adhesive layer made of VOₓSi_{y} material. This is a manufacturing technology of single-layer target material; only one layer of target material is used to form a metal electrode, with the advantages of high processing efficiency and reduction of manufacturing cost.

Preferably, in the step B1, a thickness of a film formed by the target material of the copper-vanadium alloy is 200-300 nm. This is a value range of the thickness of the target material in the technology of the single-layer target material.

Preferably, the step B comprises:

B1-1. Splashing the target material of the copper-vanadium alloy onto the surface of the base material of the array substrate;

B1-2. Splashing a target material of pure copper on a surface of the target material of the copper-vanadium alloy; and

B1-3. Splashing the target material of the copper-vanadium alloy onto the target material of pure copper.

B2 Annealing in vacuum environment; the vanadium atom in the target material of the copper-vanadium alloy gathers on the surface and reacts with silicon in the array substrate to form the adhesive layer made of VOₓSi_{y} material. A pure-copper conducting layer is formed in the middle of metal electrode formed by the technical scheme; thus, the metal electrode has good conducting effect.

Preferably, the thickness of the film formed by the target material of the copper-vanadium alloy in the step B1-1 is 10-30 nm; the thickness of the film formed by the pure copper in the step B1-2 is 250-500 nm; and the thickness of the film formed by the target material of the copper-vanadium alloy in the step B1-3 is 10-30 nm. This is a value range of the thickness of each target material in the technology of a three-layer target material.

Preferably, in the step B2, a vacuum environment is10⁻²-10⁻³ Pa; an annealing temperature is 300-350° C. and an annealing duration is 35 minutes. This is a specific temperature range together with vacuum environment.

Preferably, in the step A and step B, the content of vanadium in the target material of the copper-vanadium alloy is 7-15 at %. In this range, the adhesive layer or the barrier layer has adequate firmness and protecting property; and the thickness is proper to avoid influencing subsequent processing efficiency due to extra thickness.

On one side of the metal electrode of the present disclosure, vanadium and silicon in the array substrate (such as glass, a n+a-Si layer) have a chemical reaction to create the adhesive layer made of VOₓSi_{y} material. Thus, the metal electrode can be firmly fixed to the base material of glass; meanwhile, VOₓSi_{y} has low contact resistance so that the metal layer has good conducting property. The present disclosure also discloses a manufacturing method; the target material of the copper-vanadium alloy is only required to be splashed onto the silicon material of the array substrate to form the metal electrode with the adhesive layer made of VOₓSi_{y} material under certain vacuum and temperature conditions; the method is simple and efficient.

### BRIEF DESCRIPTION OF FIGURES

FIG. 1 is a sectional view of an array substrate of the present disclosure;

FIG. 2 is a curve diagram of a target material of a Cu—V alloy in a stable solid solution state;

FIG. 3 is a schematic diagram of example 1 of the present disclosure;

FIG. 4 is a schematic diagram of example 2 of the present disclosure;

FIG. 5 is a contrast diagram of contact resistances of pure copper and a Cu—V alloy of the present disclosure;

Legends: 100. base material of glass; 200. conducting layer; 210. first conducting layer; 220. second conducting layer; 230. third conducting layer; 300. adhesive layer; 400. barrier layer; 500. vanadium atom; 600. copper; 700. insulating layer; 800. transparent electrode layer; 900. gate electrode.

### DETAILED DESCRIPTION

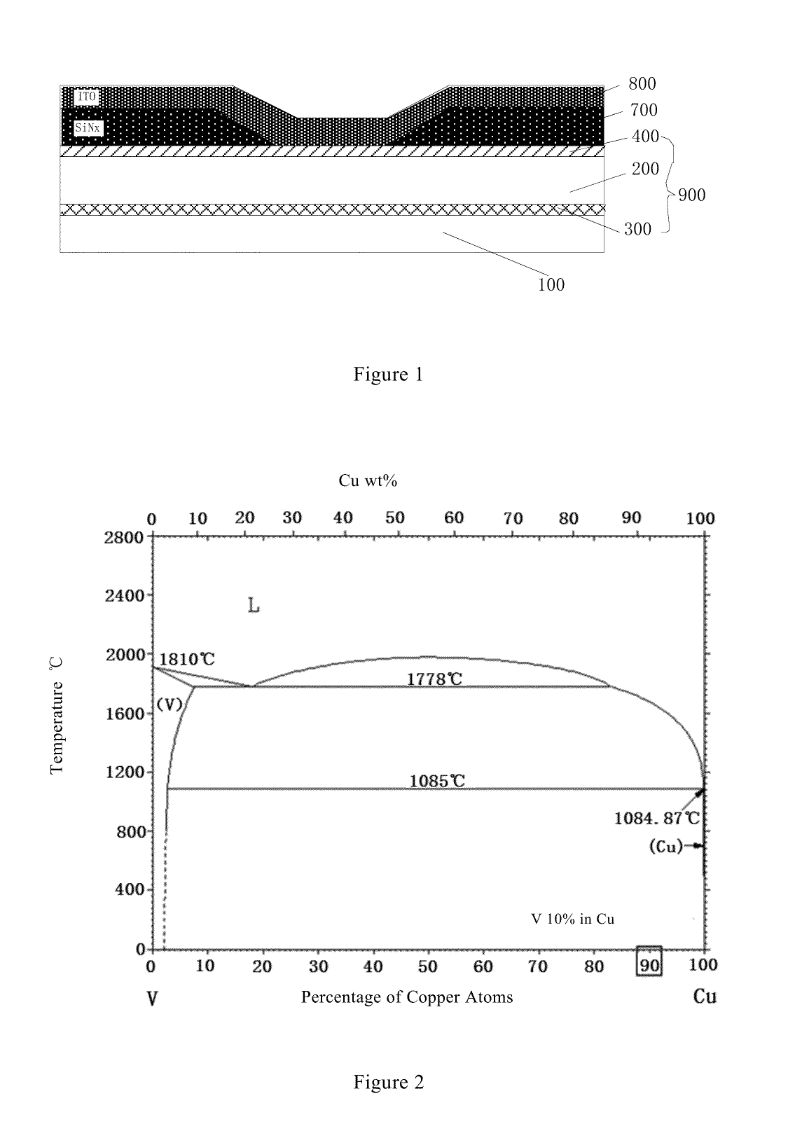

The present disclosure discloses an LCD device; the LCD device comprises an LCD panel; the LCD panel comprises a color film substrate and a TFT-LCD array substrate. The array substrate comprises a plurality of TFTs and a plurality of data lines and scan lines which are crossed. The TFT comprises a source electrode, a gate electrode, and a drain electrode; the gate electrode of each TFT is connected to one scan line, and the source electrode of each TFT is connected to one data line. Taking the sectional structure of the gate electrode as an example, as shown in FIG. 1, the structure of the array substrate sequentially comprises a base material of glass 100, a gate electrode 900, an insulating layer 700, and a transparent electrode layer 800 from the bottom. One side of the gate electrode in contact with the base material of glass is provided with an adhesive layer 300 made of VOₓSi_{y} material, and the other side is provided with a barrier layer 400; a conducting layer 200 is arranged between the adhesive layer 300 and the barrier layer 400. Optionally, a metal electrode of the present disclosure can also be one or more of the source electrode of TFT, the drain electrode of TFT, the scan line, and the data line. In addition, the metal electrode may not be directly sputtered onto the base material of glass 100; for example, the source electrode and drain electrode are arranged on a surface of a n+a-Si layer, vanadium and the n+a-Si have a chemical reaction to create VOₓSi_{y}.

On one side of the metal electrode of the present disclosure in contact with glass, vanadium comes into contact with glass, and has a chemical reaction to form an adhesive layer made of VOₓSi_{y} material, which enable the metal electrode to be firmly fixed on the base material of glass; meanwhile, VOₓSi_{y} has low contact resistance so that the metal layer has good conducting property. The present disclosure also discloses a manufacturing method; a target material of a copper-vanadium alloy is only required to be splashed onto the glass substrate to form the metal electrode with the adhesive layer made of VOₓSi_{y} material under certain vacuum and temperature conditions; the manufacturing method is simple and efficient. The present disclosure will further be described in detail in accordance with the figures and the preferable examples.

### EXAMPLE 1

In the example, a metal electrode comprises an adhesive layer 300 and a conducting layer 200 arranged on the adhesive layer 300; the conducting layer 200 can be made of copper, silver, gold and the like which have favorable conducting property; the conducting layer 200 contains 0.7-2 at % of vanadium; the conducting layer 200 is provided with a barrier layer 400 made of VOₓ material; the barrier layer 400 can prevent the conducting layer 200 from being oxidized.

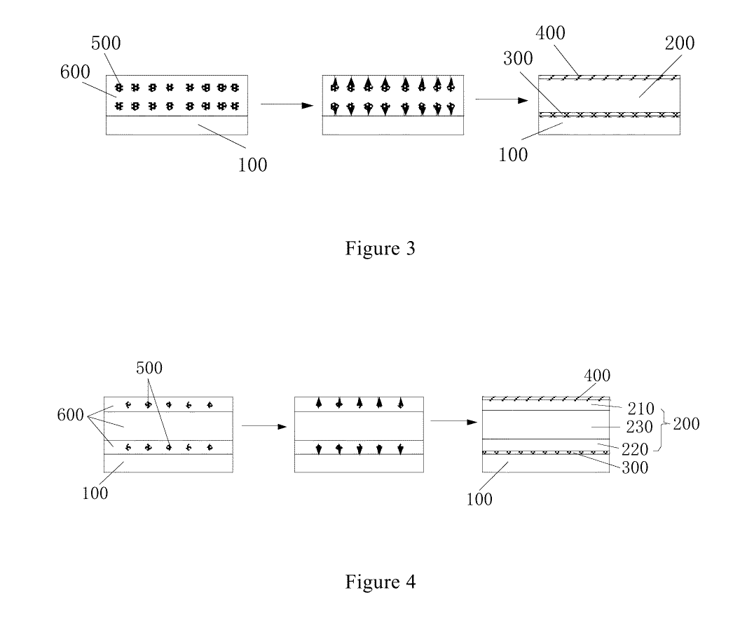

Taking copper as an example, the metal electrode can be made by using a target material of a Cu—V alloy; the specific steps are as follows (refer to the FIG. 3):

A: The vanadium (V) content in the target material of the Cu—V alloy is 8 at %; the target material of the Cu—V alloy is kept in a stable solid solution state of the metal. The temperature under which the Cu—V alloys with different proportions are in the solid solution state of the metal can be looked up from FIG. 2. Optionally, the vanadium content in the target material of the Cu—V alloy can be 7-15 at %.

B: The target material of the Cu—V alloy in the solid solution state is put into a splashing cavity, and is splashed onto a base material of glass 100 in a sputtering mode to form a metal film with a thickness of 250-500 nm. In the splashing process, an array substrate is heated to 100-150° C. and the splashing cavity is heated to 100-150° C. Optionally, the splashing thickness of the target material mainly depends on the process requirements and is not limited to the thickness range in the example.

C: In the environment with a vacuum degree of 10⁻²-10⁻³ Pa, the base material of glass 100 sputtered with the metal film of the Cu—V alloy is put into an annealing furnace and is heated to 300-350° C. for 3-5 minutes, so that vanadium 500 of a body-centered cubic structure can be sufficiently diffused in copper 600 of a face-centered cubic structure and can gathers on an upper surface and a lower surface of the metal film. Because V has favorable oxidation resistance, VOₓ of the thickness of several nanometers is created on the upper surface to form the barrier layer 400, which effectively blocks Cu from being further oxidized. V gathering to the lower surface has the thickness of several nanometers, and creates VOₓSi_{y} arranged between the metal film and glass; VOₓSi_{y} has favorable adhesiveness and forms the adhesive layer 300. Because most of V accumulate on the upper and lower surfaces of the metal film, the conducting layer 200 made of copper material is naturally formed in the middle of the metal film. The conducting layer 200 made by the method of the present disclosure has some V residues; considering the conducting property and the manufacturing cost of the conducting layer 200, it is a preferable technical scheme to control the V residues at 0.7-2 at %.

D: The metal film is etched by an etching solution of an acid mixture which is suitable for an etching of Cu, such as phosphoric acid, sulfuric acid, persulfuric acid, nitric acid, an azole compound, an amine compound, a pH stabilizing agent, an organic solvent, deionized water and the like, to form the metal electrode. Because the barrier layer 400 made of VOₓ material and the adhesive layer 300 made of VOₓSi_{y} material formed respectively on the upper and lower surfaces of the conducting layer 200 are thin, and easily dissolve in an etching acid of Cu, which ensure the smooth manufacturing of the metal electrode.

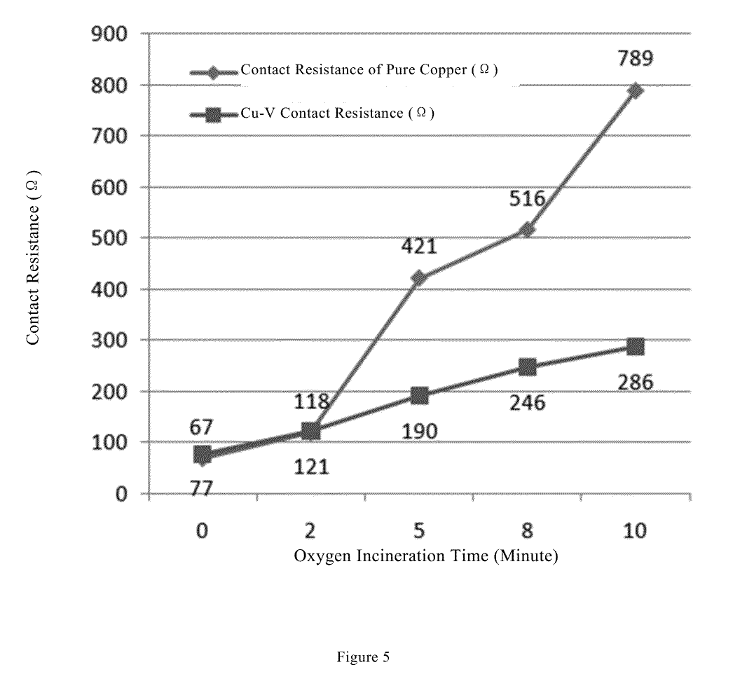

As shown in FIG. 5, in subsequent ITO manufacturing, a contact resistance of an oxidizing layer formed by the Cu—V alloy and O₂ during the O₂ incineration is obviously lower than a contact resistance of pure copper; it indicates that the method can meet the requirement of the Cu manufacturing of the TFT-LCD array substrate.

In addition, the metal electrode in the example may not be directly sputtered onto the base material of glass 100; for example, the source electrode and drain electrode are sputtered onto a surface of an n+a-Si layer; V accumulates on the lower surface and reacts with the n+a-Si to create VOxSiy. V gathers to form the adhesive layer 300 made of VOₓSi_{y} material with the thickness of several nanometers; the adhesive layer 300 is between the conducting layer and the n+a-Si for blocking a diffusion reaction between Cu and Si which forms a CuSi₃ layer with very high contact resistance.

### EXAMPLE 2

In the example, the conducting layer 200 of the metal electrode comprises a first conducting layer 210 which is integrally formed with the adhesive layer 300, a second conducting layer 220 which is integrally formed with the barrier layer 400 made of VOₓ material, and a third conducting layer 230 which is independently arranged between the first conducting layer 210 and the second conducting layer 220. The first conducting layer 210 and the second conducting layer 220 contain 0.7-2 at % of vanadium. The independent third conducting layer 230 can be made of high-purity metal, such as copper, silver, gold and the like, which improves the conducting property of the conducting layer 200.

Taking copper as an example, the metal electrode can be formed by splashing two target materials of the Cu—V alloy and one target material of pure copper; the specific steps are as follows (refer to FIG. 4):

A: The vanadium (V) content in the target material of the Cu—V alloy is 8 at %. The target material of the Cu—V alloy is kept in a stable solid solution state of the metal; similarly, the target material of pure copper is required to be in a solid solution state. The temperature under which the Cu—V alloys with different proportions are in the solid solution state of the metal can be looked up from FIG. 2. Optionally, the vanadium content in the target material of the Cu—V alloy can be 7-15 at %.

B: The target materials of the Cu—V alloy in the solid solution state are respectively put into a first splashing cavity and a third splashing cavity; the target material of pure copper is put into a second splashing cavity. Sputtering work is performed by selecting the first, the second, and the third splashing cavities sequentially. A first film of the Cu—V alloy with the thickness of 10-30 nm, a film of pure copper with the thickness of 250-500 nm, and a second film of the Cu—V alloy with the thickness of 10-30 nm are formed sequentially on the surface of the base material of glass 100. In the splashing process, the array substrate is heated to 100-150° C. and the splashing cavities are heated to 100-150° C. Optionally, the splashing thickness of each target material mainly depends on process requirements and is not limited to the thickness range in the example.

C: In the vacuum environment with the vacuum degree of 10⁻²-10⁻³ Pa, the base material of glass 100 is put into the annealing furnace and heated to 300-350° C. for 3-5 minutes, so that vanadium 500 of a body-centered cubic structure can be sufficiently diffused in copper 600 of a face-centered cubic structure:

Vanadium in the first film of the Cu—V alloy gathers on the lower surface of the film, and the thickness is several nanometers. Vanadium and the base material of glass 100 have a chemical reaction to create an adhesive layer 300 made of VOₓSi_{y} material. The rest of the first film of the Cu—V alloy naturally forms a first conducting layer 210; the main component of the first conducting layer 210 is copper; optionally, some vanadium residues are remained. Considering the conducting property and the manufacturing cost of the conducting layer 200, it is a preferable technical scheme to control the V residues at 0.7-2 at %.

The second conducting layer 220 is made of pure copper material, which is directly splashed onto the surface of the first film of the Cu—V alloy, and is joined with the first conducting layer 210.

The third film of the Cu—V alloy is splashed onto the surface of the second conducting layer 220. Vanadium in the target material gathers on the upper surface of the film; and the thickness is several nanometers. Vanadium and outside oxygen have a chemical reaction to create the barrier layer 400 made of VOₓ. The rest of the third film of the Cu—V alloy naturally forms the third conducting layer 230, which is joined with the second conducting layer 220. The main component of the third conducting layer 230 is copper; optionally, some vanadium residues are remained. Considering the conducting property and the manufacturing cost of the conducting layer 200, it is a preferable technical scheme to control the V residues at 0.7-2 at %.

D: The metal film is etched by an etching solution of an acid mixture which is suitable for the etching of Cu, such as phosphoric acid, sulfuric acid, persulfuric acid, nitric acid, an azole compound, an amine compound, a pH stabilizing agent, an organic solvent, deionized water and the like, to form the metal electrode. Because the barrier layer 400 made of VOₓ and the adhesive layer 300 made of VOₓSi_{y} formed respectively on the upper and lower surfaces of the conducting layer 200 are thin, and easily dissolve in the etching acid of Cu, which ensure the smooth manufacturing of the metal electrode.

As shown in FIG. 5, in subsequent ITO manufacturing, the contact resistance of an oxidizing layer VOₓ formed by the Cu—V alloy and O2 during the O2 incineration is obviously lower than the contact resistance of pure copper; it indicates that the method can meet the requirement of the Cu manufacturing of the TFT-LCD array substrate.

In addition, the metal electrode in the example may not be directly sputtered onto the base material of glass 100; for example, the source electrode and drain electrode are splashed on a surface of the n+a-Si layer; V accumulates on the lower surface and reacts with the n+a-Si to create VOₓSi_{y}. V gathers to form the adhesive layer 300 made of VOₓSi_{y} material with the thickness of several nanometers; the adhesive layer 300 is between the conducting layer and the n+a-Si for blocking a diffusion reaction between Cu and Si which creates a CuSi₃ layer with very high contact resistance.

Optionally, in reality, copper without any impurity does not exist; thus, the “pure copper” of the present disclosure is not limited to absolutely pure copper; the material considered to be copper material conventionally, rather than the alloy of copper, should be considered to belong to the range of pure copper of the present disclosure.

### EXAMPLE 3

The example discloses another method for manufacturing the array substrate. Pure vanadium and pure copper are put into different splashing cavities; firstly, a layer of vanadium is splashed; after that, a layer of copper is splashed; finally, a layer of vanadium is splashed again. In the vacuum and temperature environment of the example, vanadium on the lower surface creates VOₓSi_{y}; vanadium on the upper surface creates VOₓ after being incinerated with oxygen; one layer of copper in the middle forms the conducting layer. By adopting the mode, the vanadium content in the conducting layer is obviously reduced and the conducting property of the conducting layer is enhanced.

The present disclosure is described in detail in accordance with the above contents with the specific preferred examples. However, this present disclosure is not limited to the specific examples. For the ordinary technical personnel of the technical field of the present disclosure, on the premise of keeping the conception of the present disclosure, the technical personnel can also make simple deductions or replacements, and all of which should be considered to belong to the protection scope of the present disclosure.

We claim:

1. A thin film transistor liquid crystal display (TFT-LCD) array substrate, comprising:
a metal electrode comprising a conducting layer;
wherein one side of the conducting layer is provided with an adhesive layer made of VOₓSi_{y} material, and the other side is provided with a barrier layer.

2. The TFT-LCD array substrate of claim 1, wherein the conducting layer is made of copper-vanadium alloy, the vanadium content is 0.7-2 at %.

3. The TFT-LCD array substrate of claim 1, wherein the conducting layer comprises a first conducting layer integrally formed with the adhesive layer, a second conducting layer integrally formed with the barrier layer, and a third conducting layer independently arranged between the first conducting layer and the second conducting layer.

4. The TFT-LCD array substrate of claim 3, wherein the first conducting layer and second conducting layer are made of copper-vanadium alloy, the vanadium content is 0.7-2 at %, and the third conducting layer is made of pure copper material.

5. The TFT-LCD array substrate of claim 1, wherein the barrier layer is made of VOₓ material.

6. A liquid crystal display (LCD) device, comprising:
a thin film transistor liquid crystal display (TFT-LCD) array substrate comprising a metal electrode;
wherein the metal electrode comprises a conducting layer;
wherein one side of the conducting layer is provided with an adhesive layer made of VOₓSi_{y} material, and the other side is provided with a barrier layer.

7. The LCD device of claim 6, wherein the conducting layer is made of copper-vanadium alloy, the vanadium content is 0.7-2 at %.

8. The LCD device of claim 6, wherein the conducting layer comprises a first conducting layer integrally formed with the adhesive layer, a second conducting layer integrally formed with the barrier layer, and a third conducting layer independently arranged between the first conducting layer and second conducting layer.

9. The LCD device of claim 8, wherein the first conducting layer and the second conducting layer are made of copper-vanadium alloy, the vanadium content is 0.7-2 at %, and the third conducting layer is made of pure copper material.

10. The LCD device of claim 6, wherein the barrier layer is made of VOₓ material.

11. A method for manufacturing a thin film transistor liquid crystal display (TFT-LCD) array substrate, comprising:
A. Preparing a target material of a copper-vanadium alloy and a base material of an array substrate; keeping the target material of the copper-vanadium alloy in a solid solution state; and heating the base material;
B. Paving the target material of the copper-vanadium alloy onto a surface of the base material the array substrate to form a metal layer with an adhesive layer made of VOₓSi_{y} material.

12. The method for manufacturing the TFT-LCD array substrate of claim 11, wherein in the step A, the target material the copper-vanadium alloy is kept at 100-150° C.; and the array substrate is heated to 100-150° C.

13. The method for manufacturing the TFT-LCD array substrate of claim 11, wherein the method comprises a step C after the step B: incinerating the array substrate; a vanadium atom in the target material the copper-vanadium alloy reacts with oxygen to create a barrier layer made of VOₓ material on the other opposite side of the adhesive layer.

14. The method for manufacturing the TFT-LCD array substrate of claim 11, wherein the step B comprises the steps:
B1. Splashing the target material of the copper-vanadium alloy onto the surface of the base material of the array substrate;
B2. Annealing in vacuum environment; a vanadium atom in the target material of the copper-vanadium alloy gathers on the surface and reacts with a silicon material of the array substrate to create the adhesive layer made of VOₓSi_{y} material.

15. The method for manufacturing the TFT-LCD array substrate of claim 14, wherein in the step B1, a thickness of a film formed by the target material of the copper-vanadium alloy is 200-300 nm.

16. The method for manufacturing the TFT-LCD array substrate of claim 11, wherein the step B comprises the steps:
B1-1. Splashing the target material of the copper-vanadium alloy onto the surface of the base material the array substrate;
B1-2. Splashing a target material of pure copper on a surface of the target material of the copper-vanadium alloy;
B1-3. Splashing the target material of the copper-vanadium alloy on the target material of pure copper; and
B2. Annealing in vacuum environment; a vanadium atom in the target material of the copper-vanadium alloy gathers on the surface and reacts with a silicon material of the array substrate to create the adhesive layer made of VOₓSi_{y} material.

17. The method for manufacturing the TFT-LCD array substrate of claim 16, wherein:
a thickness of a film formed by the target material of the copper-vanadium alloy in the step B1-1 is 10-30 nm;
a thickness of a film formed by pure copper in the step B1-2 is 250-500 nm;
the thickness of the film formed by the target material of the copper-vanadium alloy in the step B1-3 is 10-30 nm.

18. The method for manufacturing the TFT-LCD array substrate of claim 14 or claim 16, wherein in the step B2, a vacuum environment is 10⁻²-10⁻³ Pa; a temperature of an annealing furnace is 300-350° C.; an annealing duration is 3-5 minutes.

19. The method for manufacturing the TFT-LCD array substrate of claim 11, wherein in the step A and the step B, the vanadium content in the target material of the copper-vanadium alloy is 7-15 at %.
